(19) United States
(12) Patent Application Publication
(10) Pub. No.: US 2026/0016551 A1
(43) Pub. Date: Jan. 15, 2026

(54) MAGNETIC RESONANCE SYSTEM, MAGNETIC RESONANCE IMAGING SEQUENCE, AND OPTIMIZATION METHOD

(71) Applicant: GE Precision Healthcare LLC, Waukesha, WI (US)

(72) Inventors: Wei Chang, Beijing (CN); Lei Gao, Beijing (CN); Yongchuan Lai, Beijing (CN)

(21) Appl. No.: 19/271,766

(22) Filed: Jul. 16, 2025

(30) Foreign Application Priority Data
Jul. 15, 2024 (CN) 202410968546.X

(51) Int. Cl. G01R 33/36; G01R 33/561

(52) U.S. Cl. CPC G01R 33/3607; G01R 33/561

(57) ABSTRACT

A magnetic resonance system, a magnetic resonance imaging sequence, and an optimization method are provided. The imaging sequence includes: a radio-frequency excitation pulse; a first radio-frequency refocusing pulse and a second radio-frequency refocusing pulse sequentially applied after the radio-frequency excitation pulse; original gradient pulses including a right-side original pulse and a left-side original pulse, the right-side original pulse being applied between the center of the first radio-frequency refocusing pulse and the center of the second radio-frequency refocusing pulse, the left-side original pulse being applied between the center of the radio-frequency excitation pulse and the center of the first radio-frequency refocusing pulse, and the left-side original pulse including a first gradient pulse corresponding to the radio-frequency excitation pulse; and a first balancing pulse located within a first time period between the end point of the first gradient pulse and the starting point of the first radio-frequency refocusing pulse and including a positive pulse and a negative pulse located on a first gradient axis.

### CROSS REFERENCE TO RELATED APPLICATIONS

The present application claims priority and benefit of Chinese Patent Application No. 202410968546.X filed on Jul. 18, 2024, which is incorporated herein by reference in its entirety.

### TECHNICAL FIELD

The present invention relates to the field of medical imaging, in particular to a magnetic resonance (MR) imaging sequence, an optimization method for a magnetic resonance imaging sequence, and a magnetic resonance system.

### BACKGROUND

Magnetic resonance imaging technology has become one of the most important modern image diagnostic technologies by virtue of its characteristics such as non-invasiveness, abundant diagnostic information, and high resolution. Magnetic resonance imaging technology utilizes electromagnetic principles to generate and acquire image information by executing imaging sequences (also referred to as scan sequences or pulse sequences) that match clinical diagnostic requirements, and when these imaging sequences are designed, optimized, or selected, content of various aspects such as clinical diagnostic requirements, image quality, scan safety, and scan time may be considered. For example, it is desired to perform scans as safely and quickly as possible while improving the clarity and resolution and the like of anatomical structure images.

The imaging sequence typically includes gradient pulses, and ideal gradient pulses make the magnetic field change linearly. However, during actual scans, nonlinear concomitant fields are inevitably generated along with the linear gradient field. These concomitant fields are potential sources of artifacts in magnetic resonance imaging. For instance, such concomitant fields cause undesired phase accumulation, resulting in phase errors between echo signals, and further causing signal loss, image blurring, ghosting, etc.

### SUMMARY OF THE INVENTION

An aspect of the present invention provides a magnetic resonance imaging sequence. The magnetic resonance imaging sequence includes a radio-frequency excitation pulse, a first radio-frequency refocusing pulse and a second radio-frequency refocusing pulse sequentially applied after the radio-frequency excitation pulse, original pulses, and a first balancing pulse. The original gradient pulses comprise a right-side original pulse and a left-side original pulse, the right-side original pulse being applied between the center of the first radio-frequency refocusing pulse and the center of the second radio-frequency refocusing pulse, the left-side original pulse being applied between the center of the radio-frequency excitation pulse and the center of the first radio-frequency refocusing pulse, and the left-side original pulse comprising a first gradient pulse corresponding to the radio-frequency excitation pulse. The first balancing pulse is located within a first time period between the end point of the first gradient pulse and the starting point of the first radio-frequency refocusing pulse, and the first balancing pulse comprises a positive pulse and a negative pulse located on a first gradient axis.

Another aspect of the present invention further provides an optimization method for a magnetic resonance imaging sequence, comprising step 1, step 2, and step 3. In step 1, a right-side Maxwell term generated by a right-side original pulse and a left-side Maxwell term generated by a left-side original pulse are determined. In step 2, in response to the right-side Maxwell term being greater than the left-side Maxwell term and a first difference between the right-side Maxwell term and the left-side Maxwell term being greater than a preset value, based on a current echo spacing of the magnetic resonance imaging sequence, a maximum value of a first compensatory Maxwell term that is capable of being generated on a first gradient axis is determined. In step 3, a first balancing pulse disposed on the first gradient axis is determined to increase the left-side Maxwell term, and in response to the maximum value being greater than the first difference, the amplitude of the first balancing pulse is less than a maximum amplitude; and in response to the maximum value being equal to the first difference, the amplitude of the first balancing pulse is equal to the maximum amplitude. The first balancing pulse is located within a first time period between the end point of a first gradient pulse and the starting point of a first radio-frequency refocusing pulse, and the first balancing pulse comprises a positive pulse and a negative pulse.

Yet another aspect of the present invention further provides a magnetic resonance imaging system comprising a scanner and a processor, wherein the processor is configured to execute the optimization method for a magnetic resonance imaging sequence according to any one of the above aspects, or control the scanner to execute the magnetic resonance imaging sequence according to any one of the above aspects.

It should be understood that the brief description above is provided to introduce, in a simplified form, concepts that will be further described in the detailed description. The brief description above is not meant to identify key or essential features of the claimed subject matter. The scope is defined uniquely by the claims that follow the detailed description. Furthermore, the claimed subject matter is not limited to implementations that solve any deficiencies raised above or in any section of the present disclosure.

### BRIEF DESCRIPTION OF THE DRAWINGS

The present invention will be better understood by reading the following description of non-limiting examples with reference to the accompanying drawings, wherein

FIG. 1 is a schematic diagram of a magnetic resonance (MR) system according to an exemplary embodiment;

FIG. 2 is a waveform diagram of a magnetic resonance imaging sequence according to an embodiment of the present invention;

FIG. 3 is a waveform diagram of a magnetic resonance imaging sequence according to an embodiment of the present invention;

FIG. 4 is a waveform diagram of a magnetic resonance imaging sequence according to an embodiment of the present invention;

FIG. 5 is a waveform diagram of a magnetic resonance imaging sequence according to an embodiment of the present invention;

FIG. 6 is a waveform diagram of a magnetic resonance imaging sequence according to an embodiment of the present invention;

FIG. 7 is a waveform diagram of a magnetic resonance imaging sequence according to an embodiment of the present invention;

FIG. 8 is a flowchart of an optimization method for a magnetic resonance imaging sequence according to an embodiment of the present invention;

FIG. 9 is a flowchart of an optimization method for a magnetic resonance imaging sequence according to another embodiment of the present invention; and

FIG. 10 is a flowchart of an optimization method for a magnetic resonance imaging sequence according to yet another embodiment of the present invention.

The drawings illustrate components, sequences or waveforms, systems, and methods described in various embodiments of the present invention. Together with the following description, the accompanying drawings illustrate and explain structural principles, methods, and principles described herein. In the accompanying drawings, the thickness and dimensions of the components may be enlarged or otherwise modified for clarity. Well-known structures, materials, or operations are not shown or described in detail to prevent the described components, systems, and methods from being obscured.

### DETAILED DESCRIPTION

Specific implementations of the present invention will be described below. It should be noted that in the specific description of said implementations, for the sake of brevity and conciseness, the present description cannot describe all of the features of the actual implementations in detail. It should be understood that in the actual implementation process of any implementation, just as in the process of any one engineering project or design project, a variety of specific decisions are often made to achieve specific goals of the developer and to meet system-related or business-related constraints, which may also vary from one implementation to another. Furthermore, it should also be understood that although efforts made in such development processes may be complex and tedious, for those of ordinary skill in the art related to the content disclosed in the present invention, some design, manufacture, or production changes made on the basis of the technical content disclosed in the present disclosure are only common technical means, and should not be construed as the content of the present disclosure being insufficient.

Unless otherwise defined, the technical or scientific terms used in the claims and the description should be as they are usually understood by those possessing ordinary skill in the technical field to which they belong. Terms such as “first”, “second”, and similar terms used in the present description and claims do not denote any order, quantity, or importance, but are only intended to distinguish different constituents. The terms “one” or “a/an” and similar terms do not express a limitation of quantity, but rather that at least one is present. The terms “include”, “comprise”, or similar terms indicate that an element or object preceding the term “include” or “comprise” encompasses elements or objects and equivalent elements thereof listed after the term “include” or “comprise”, and does not exclude other elements or objects. The terms “connect” or “link” and similar words are not limited to physical or mechanical connections, and are not limited to direct or indirect connections. Furthermore, it should be understood that references to “an embodiment” or “embodiments” of the present disclosure are not intended to be construed as excluding the existence of additional implementations that also incorporate the referenced features.

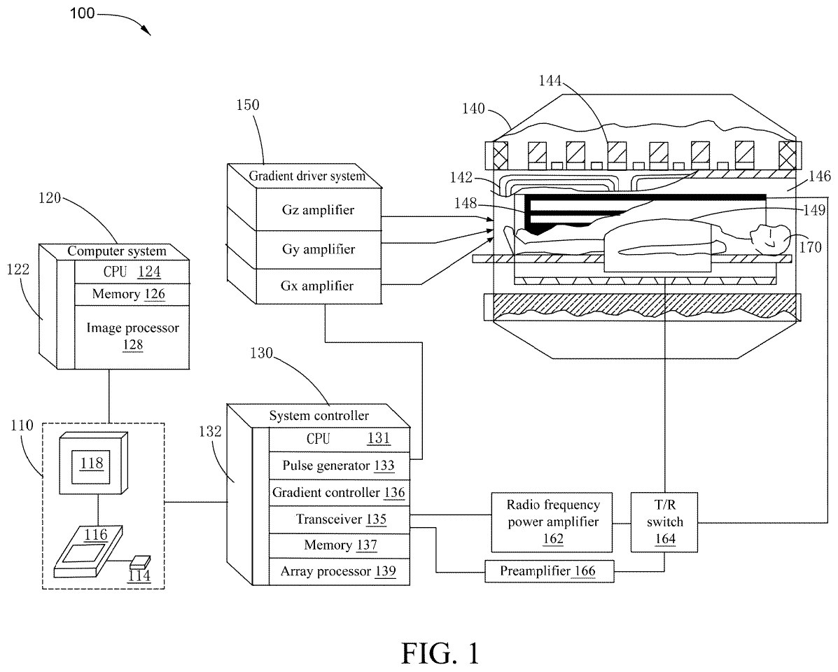

Referring to FIG. 1, a schematic diagram of an exemplary magnetic resonance (MR) system 100 according to some embodiments is illustrated. The operation of the MR system 100 is controlled by an operator workstation 110 that includes an input device 114, a control panel 116, and a display 118. The input device 114 may be a joystick, a keyboard, a mouse, a trackball, a touch-activated screen, voice control, or any similar or equivalent input device. The control panel 116 may include a keyboard, a touch-activated screen, voice control, a button, a slider, or any similar or equivalent control device. The operator workstation 110 is coupled to and in communication with a computer system 120 that enables an operator to control the generation and display of images on the display 118. The computer system 120 includes various components that communicate with one another by means of an electrical and/or data connection module 122. The connection module 122 may employ a direct wired connection, a fiber optic connection, a wireless communication link, etc. The computer system 120 may include a central processing unit (CPU) 124, a memory 126, and an image processor 128. In some embodiments, the image processor 128 may be replaced by image processing functions implemented in the CPU 124. The computer system 120 may be connected to an archive media device, a persistent or backup memory, or a network. The computer system 120 may be coupled to and communicate with a separate system controller 130.

The system controller 130 includes a set of components that communicate with one another by means of an electrical and/or data connection module 132. The connection module 132 may employ a direct wired connection, a fiber optic connection, a wireless communication link, etc. The system controller 130 may include a CPU 131, a sequence pulse generator 133 communicating with the operator workstation 110, a transceiver (or an RF transceiver) 135, a memory 137, and an array processor 139. In some embodiments, the sequence pulse generator 133 may be integrated into the resonance assembly 140 of the MR system 100. The system controller 130 may receive a command from the operator workstation 110 to indicate an MR scan sequence that is to be executed during an MR scan. The system controller 130 is further coupled to and in communication with a gradient driver system 150, which is coupled to a gradient coil assembly 142 to generate a magnetic field gradient during the MR scan.

The sequence pulse generator 133 may further receive data from a physiological acquisition controller 155 that receives signals from a plurality of different sensors (e.g., electrocardiogram (ECG) signals from electrodes attached to a patient), the sensors being connected to a subject or patient 170 undergoing an MR scan. The sequence pulse generator 133 is coupled to and in communication with a scan room interface system 145 that receives signals from various sensors associated with the state of the resonance assembly 140. The scan room interface system 145 is further coupled to and in communication with a patient positioning system 147 that sends and receives signals to control movement of a patient table to a desired position to perform the MR scan.

The system controller 130 provides gradient waveforms to the gradient driver system 150, and the gradient driver system includes Gₓ, G_{y}, and G_{z} amplifiers, etc. Each of the Gₓ, G_{y}, and G_{z} gradient amplifiers excites a corresponding gradient coil in the gradient coil assembly 142, so as to generate a magnetic field gradient used to spatially encode an MR signal during the MR scan. The gradient coil assembly 142 is disposed within the resonance assembly 140, and the resonance assembly further includes a superconducting magnet having a superconducting coil 144 that, in operation, provides a static uniform longitudinal magnetic field B₀ throughout a cylindrical imaging volume 146. The resonance assembly 140 further includes an RF body coil 148, which, in operation, provides a transverse magnetic field B₁, the transverse magnetic field B₁ being substantially perpendicular to B₀ throughout the entire cylindrical imaging volume 146. The resonance assembly 140 may further include an RF surface coil 149 for imaging different anatomical structures of the patient undergoing the MR scan. The RF body coil 148 and the RF surface coil 149 may be configured to operate in a transmit and receive mode, a transmit mode, or a receive mode.

The subject or patient 170 of the MR scan may be positioned within the cylindrical imaging volume 146 of the resonance assembly 140. The transceiver 135 in the system controller 130 generates RF excitation pulses that are amplified by an RF amplifier 162 and provided to the RF body coil 148 through a transmit/receive switch (T/R switch) 164.

As described above, the RF body coil 148 and the RF surface coil 149 may be used to transmit RF excitation pulses and/or receive resulting MR signals from the patient undergoing the MR scan. The MR signals emitted by excited nuclei in the patient of the MR scan may be sensed and received by the RF body coil 148 or the RF surface coil 149 and sent back to a preamplifier 166 through the T/R switch 164. The T/R switch 164 may be controlled by a signal from the sequence pulse generator 133 to electrically connect the RF amplifier 162 to the RF body coil 148 in the transmit mode and to connect the preamplifier 166 to the RF body coil 148 in the receive mode. The T/R switch 164 may further enable the RF surface coil 149 to be used in the transmit mode or the receive mode.

In some embodiments, the MR signals sensed and received by the RF body coil 148 or the RF surface coil 149 and amplified by the preamplifier 166 are stored in the memory 137 for post-processing as a raw k-space data array. A reconstructed magnetic resonance image may be obtained by transforming/processing the stored raw k-space data.

In some implementations, the MR signals sensed and received by the RF body coil 148 or the RF surface coil 149 and amplified by the preamplifier 166 are demodulated, filtered, and digitized in a receiving portion of the transceiver 135, and transmitted to the memory 137 in the system controller 130. For each image to be reconstructed, the data is rearranged into separate k-space data arrays, and each of said separate k-space data arrays is input to the array processor 139, the array processor being operated to transform the data into an array of image data by Fourier transform.

The array processor 139 uses transform methods, most commonly Fourier transform, to create images from the received MR signals. These images are transmitted to the computer system 120 and stored in the memory 126. In response to commands received from the operator workstation 110, the image data may be stored in a long-term memory, or may be further processed by the image processor 128 and transmitted to the operator workstation 110 for presentation on the display 118.

In various embodiments, components of the computer system 120 and the system controller 130 may be implemented on the same computer system or on a plurality of computer systems. It should be understood that the MR system 100 shown in FIG. 1 is intended for illustration. Suitable MR systems may include more, fewer, and/or different components.

The system controller 130 and the image processor 128 may separately or collectively include a computer processor and a storage medium. The storage medium has recorded thereon a predetermined data processing program to be executed by the computer processor. For example, the storage medium may store a program used to implement scanning processing (such as a scan flow and an imaging sequence), image reconstruction, image processing, etc. For example, the storage medium may store a magnetic resonance imaging sequence according to the embodiments of the present invention and a program used to implement an optimization method for a magnetic resonance imaging sequence according to the embodiments of the present invention. The described storage medium may include, for example, a ROM, a floppy disk, a hard disk, an optical disk, a magneto-optical disk, a CD-ROM, or a non-volatile memory card.

The aforementioned “imaging sequence” refers to a combination of pulses having specific amplitudes, widths, directions, and time sequences and applied when a magnetic resonance imaging scan is executed. The pulses may typically include, for example, radio-frequency pulses and gradient pulses. The radio-frequency pulses may include, for example, radio-frequency excitation pulses, radio-frequency refocusing pulses, inverse recovery pulses, etc. The gradient pulses may include, for example, the aforementioned gradient pulse used for layer selection, gradient pulse used for phase encoding, gradient pulse used for frequency encoding, gradient pulse used for phase shifting (phase shift), gradient pulse used for dispersion of phases (dephasing), etc.

Generally, a plurality of scan sequences may be preset in the magnetic resonance system, so that a sequence suitable for clinical test requirements can be selected. The clinical test requirements may include, for example, a site to be imaged, an image quality, etc. For example, an imaging sequence provided according to any embodiment of the present invention may be preset to obtain diagnostic images having reduced blurring or artifacts.

In existing imaging sequences, a plurality of radio-frequency refocusing pulses may be applied after a radio-frequency excitation pulse, a changed phase encoding gradient pulse may be applied between every two adjacent radio-frequency refocusing pulses, and echo signals are acquired during this period, so that a plurality of phase encoding lines in a k-space are filled within one repetition time (TR), thereby reducing the imaging time. Such imaging sequences include a fast spin echo (FSE) sequence, also known as a turbo spin echo (TSE) sequence.

Magnetic resonance technology utilizes electromagnetic principles for imaging, and follows Maxwell's Equations as follows:

$$∇ \times B = {μ}_{0} ( J + {ε}_{0} \frac{\partial E}{\partial t} ) ; \qquad ( 1 )$$

$$∇ \times E = - \frac{\partial B}{\partial t} ; \qquad ( 2 )$$

$$∇ \cdot B = 0 ; and \qquad ( 3 )$$

$$∇ \cdot D = ρ ; \qquad ( 4 )$$

where ∇ is an operator, B is a magnetic field strength, μ₀ is a magnetic permeability, J is a current density, ε₀ is a dielectric constant, E is an electric field strength, t is a time, and ρ is a free charge density.

Since a time-variable electric field and a current density in a human body may be ignored when the human body is imaged using a magnetic resonance system, Equation (1) yields the following equation:

$$∇ \times B = 0. \qquad ( 5 )$$

Based on Equations (3) and (5), main components of a magnetic field of the magnetic resonance system are derived, as shown in the following equation:

$$B = {B}_{0} + {G}_{x} x + {G}_{y} y + {G}_{z} z + \frac{1}{2 {B}_{0}} \{ ( {G}_{x}^{2} + {G}_{z}^{2} ) {y}^{2} + {G}_{y}^{2} \frac{{x}^{2} + {z}^{2}}{4} - {G}_{x} {G}_{y} x y - {G}_{z} {G}_{y} yz \} ; \qquad ( 6 )$$

where Gₓ, G_{y}, and G_{z} are linear gradient fields applied in a frequency encoding direction, a phase encoding direction, and a layer selection encoding direction, respectively, and x, y, and z represent coordinate values in the frequency encoding direction, the phase encoding direction, and the layer selection direction, respectively.

Thus, the magnetic field of the magnetic resonance system consists of a static magnetic field B₀ and gradient magnetic fields, where the gradient magnetic fields, in addition to providing required linear gradient fields, further include a concomitant field (or Maxwell field, Maxwell term, or the like), and main components of the concomitant field are expressed as:

$${B}_{m} = \frac{1}{2 {B}_{0}} \{ ( {G}_{x}^{2} + {G}_{z}^{2} ) {y}^{2} + {G}_{y}^{2} \frac{{x}^{2} + {z}^{2}}{4} - {G}_{x} {G}_{y} x y - {G}_{z} {G}_{y} yz \} \qquad ( 7 )$$

The inventors propose that a compensation field may be generated by applying an additional gradient pulse (hereinafter referred to as a compensation pulse or a balancing pulse) on a gradient axis before a first radio-frequency refocusing pulse to use a flipping effect of the radio-frequency refocusing pulse to counteract a concomitant field generated after the radio-frequency refocusing pulse.

The inventors have found that when a gradient amplitude after the first radio-frequency refocusing pulse (right side) is large, a right-side Maxwell term is difficult to balance, and a better compensation effect is achieved by applying a balancing pulse before the first refocusing pulse.

In practical applications, pulse waveform adjustment (e.g., an increase in any one of a pulse amplitude and a pulse duration) may be performed on gradient pulses of a fast spin echo sequence to achieve different clinical applications. The inventors have further found that, for example, if a concomitant field generated by the gradient pulse applied after the first radio-frequency refocusing pulse (e.g., on the right side of the sequence diagram) is too large, even if the gradient amplitude before the first radio-frequency refocusing pulse is increased to a maximum amplitude allowed by the system, the concomitant field cannot be completely compensated for, thereby causing corresponding artifacts. At this time, the concomitant field is further compensated for by extending the duration of the balancing pulse, so that an echo spacing (ESP) is increased, which may introduce issues of image blurring and prolonged scanning time.

In the fast spin echo sequence, the ESP refers to the greater of a first time spacing and a second time spacing, where the first time spacing is twice the time spacing between the center of a radio-frequency excitation pulse and the center of a first radio-frequency refocusing pulse, and the second time spacing is the time spacing between the center of the first radio-frequency refocusing pulse and the center of a second radio-frequency refocusing pulse.

Embodiment 1 of the present invention provides a magnetic resonance imaging sequence, including a radio-frequency excitation pulse, a first radio-frequency refocusing pulse and a second radio-frequency refocusing pulse sequentially applied after the radio-frequency excitation pulse, original gradient pulses, and a first balancing pulse. The original gradient pulses include a right-side original pulse and a left-side original pulse, the right-side original pulse is applied between the center of the first radio-frequency refocusing pulse and the center of the second radio-frequency refocusing pulse, the left-side original pulse is applied between the center of the radio-frequency excitation pulse and the center of the first radio-frequency refocusing pulse, and the left-side original pulse includes a first gradient pulse corresponding to the radio-frequency excitation pulse. The first balancing pulse is located within a first time period between the end point of the first gradient pulse and the starting point of the first radio-frequency refocusing pulse, and the first balancing pulse includes a positive pulse and a negative pulse located on a first gradient axis.

In some embodiments, the left-side original pulse includes a second gradient pulse applied on the first gradient axis after the radio-frequency excitation pulse, where the second gradient pulse forms at least a portion of the positive pulse or the negative pulse of the first balancing pulse.

In some embodiments, the first balancing pulse lasts throughout the first time period.

In some embodiments, the original gradient pulses comprise original gradient pulses disposed on the first gradient axis and original gradient pulses disposed on a second gradient axis, where the load of the original gradient pulses on the second gradient axis is greater than the load of the original gradient pulses on the first gradient axis.

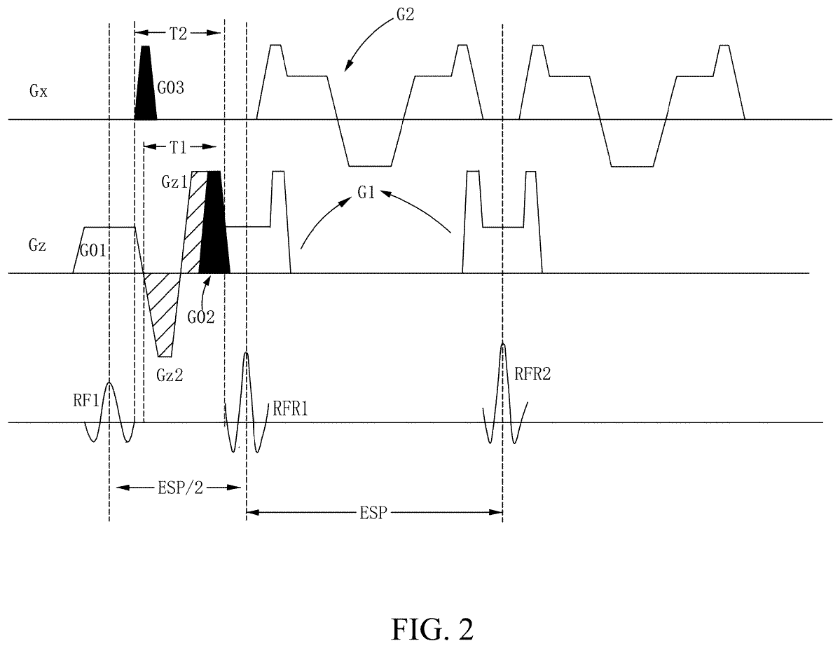

Embodiment 1 of the present invention will be described below with reference to FIGS. 2 to 4.

FIG. 2 shows a waveform diagram of a magnetic resonance imaging sequence according to an embodiment of the present invention, where the magnetic resonance imaging sequence includes a radio-frequency excitation pulse RF1, a first radio-frequency refocusing pulse RFR1 and a second radio-frequency refocusing pulse RFR2 sequentially applied after the radio-frequency excitation pulse RF1, original gradient pulses, and a first balancing pulse.

The radio-frequency excitation pulse RF1 is a 90-degree radio-frequency pulse. The first radio-frequency refocusing pulse RFR1 and the second radio-frequency refocusing pulse RFR2 may be 180-degree radio-frequency pulses or radio-frequency pulses of less than 180 degrees, which are configured to perform phase refocusing on dephased proton groups and generate corresponding echo signals (not shown in the figures) after the refocusing pulses end. Although only two radio-frequency refocusing pulses are shown in the figures, those skilled in the art will appreciate that there may be more radio-frequency refocusing pulses after the second radio-frequency refocusing pulse.

The original gradient pulses include a right-side original pulse (located on the right side of the first radio-frequency refocusing pulse RFR1) and a left-side original pulse (located on the left side of the first radio-frequency refocusing pulse RFR1). The right-side original pulse is applied between the center of the first radio-frequency refocusing pulse RFR1 and the center of the second radio-frequency refocusing pulse RFR2. The left-side original pulse is applied between the center of the radio-frequency excitation pulse RF1 and the center of the first radio-frequency refocusing pulse RFR1. The left-side original pulse includes a first gradient pulse G01 corresponding to the radio-frequency excitation pulse RF1, the first gradient pulse G01 may be, for example, a gradient pulse for layer selection, and the first gradient pulse G01 is transmitted simultaneously with the radio-frequency excitation pulse RF1 (e.g., the end point of a plateau of G01 is the same as the end point of RF1). The first balancing pulse is located within a first time period T1 between the end point of the first gradient pulse G01 and the starting point of the first radio-frequency refocusing pulse RFR1.

A right-side Maxwell term Bm1 is generated between the first radio-frequency refocusing pulse RFR1 and the second radio-frequency refocusing pulse RFR2, which is half of a Maxwell term generated by the right-side original pulse (an echo signal is generated between the first radio-frequency refocusing pulse and the second radio-frequency refocusing pulse, and the first half of the right-side original pulse generates phase accumulation errors for the echo signal). That is, a concomitant field is generated on the right side (or after) the first radio-frequency refocusing pulse RFR1. Specifically, the right-side original pulse may include a gradient pulse G1 disposed on a first gradient axis Gz and a gradient pulse G2 disposed on a second gradient axis. The right-side Maxwell term Bm1 is half of the sum of a right-side first Maxwell term generated by the gradient pulse G1 and a right-side second Maxwell term generated by the gradient pulse G2.

The left-side original pulse generates a left-side Maxwell term Bm0. When the right-side Maxwell term Bm1 is greater than the left-side Maxwell term Bm0, corresponding artifacts may arise due to a first difference between the two.

The first balancing pulse is located within the first time period, e.g., time period T1, between the end point of the first gradient pulse G01 and the starting point of the first radio-frequency refocusing pulse RFR1, and the first balancing pulse includes a positive pulse Gz1 and negative pulse Gz2.

By configuring the first balancing pulse, the left-side Maxwell term Bm0 is increased to eliminate or reduce the first difference, thereby eliminating or reducing corresponding artifacts.

As shown in FIG. 2, the left-side original pulse may further include a second gradient pulse G02 applied on the first gradient axis Gz after the radio-frequency excitation pulse RF1, and the second gradient pulse G02 forms at least a portion of the positive pulse Gz1 or the negative pulse Gz2 of the first balancing pulse. The primary initial function of the second gradient pulse G02 as an original pulse may not be to compensate for concomitant fields, but to serve other purposes. However, since it contributes a portion of the initial left-side Maxwell term Bm0, a certain compensation effect is achieved. After the first balancing pulse is determined, the second gradient pulse G02 as a whole may be used as a portion of the first balancing pulse (e.g., the positive pulse Gz1 of the first balancing pulse is formed after the width and/or amplitude of the second gradient pulse G02 is increased).

After the first balancing gradient is disposed on the first gradient axis, the first gradient axis may be fully loaded within the time period T1 (pulses are disposed on the first gradient axis in all time periods of T1, which may include the second gradient pulse G02 and the first balancing pulse). For example, within the time period T1, blank time periods outside the time period occupied by the left-side original pulse may be used to dispose additional first balancing pulses (shown as shaded areas with slashes in FIG. 2).

As shown in FIG. 2, the second gradient axis Gx may also have an original gradient pulse thereon, for example, a third gradient pulse G03 to be described below.

The first balancing pulse is configured to generate a first compensatory Maxwell term Bm2 as a compensation field to compensate for a difference between the right-side Maxwell term Bm1 and a current left-side Maxwell term Bm0. In some embodiments, an original gradient pulse may have been disposed between the radio-frequency excitation pulse RF1 and the first radio-frequency refocusing pulse RFR1 to generate an initial left-side Maxwell term, at which time, Bm0 is greater than zero. By means of the first balancing pulse, a compensation field is pre-generated before the first radio-frequency refocusing pulse RFR1 to use a flipping effect of the radio-frequency refocusing pulse to compensate for a concomitant field generated after the first radio-frequency refocusing pulse RFR1, thereby eliminating image artifacts that may be caused by the concomitant field. Furthermore, the first balancing pulse includes the positive pulse Gz1 and the negative pulse Gz2 located on the first gradient axis. Compared to applying balancing pulses in only a single direction, applying the positive pulse and the negative pulse can generate a larger Maxwell quadratic term to compensate for more (or larger) concomitant fields within a limited echo spacing and under system parameter limits (e.g., the maximum gradient pulse amplitude that can be applied by a magnetic resonance system).

In some embodiments, e.g., under ideal conditions, the difference between the right-side Maxwell term Bm1 and the left-side Maxwell term Bm0 may be fully compensated for by the first compensatory Maxwell term Bm2. This enables compensation for the concomitant field by applying balancing pulses on only a single gradient axis. For example, a compensation field is generated by applying balancing pulses on only the first gradient axis Gz without increasing an echo spacing (ESP) of an FSE sequence. This may be achieved, for example, by applying gradient pulses (e.g., the positive pulse Gz1 and the negative pulse Gz2) in both positive and negative directions. In some embodiments, when the difference between the right-side Maxwell term Bm1 and the left-side Maxwell term Bm0 is small or the first time period T1 is sufficiently long, the first compensatory Maxwell term Bm2 generated by the first balancing pulse may correspondingly be small. In such cases, the amplitude of the first balancing pulse may be small, e.g., less than a maximum amplitude allowed by the magnetic resonance system, or at least one of the positive pulse or the negative pulse of the first balancing pulse may be less than the maximum amplitude.

In some embodiments, the first balancing pulse lasts throughout the first time period T1, i.e., the waveforms of the positive pulse Gz1 and the negative pulse Gz2 of the first balancing pulse occupy (share, or cover) the entire T1. This allows a larger compensation field to be provided to compensate for the concomitant field to a greater extent, which may reduce artifacts, or in the case of a limited ESP (or limited time period T1), allows more margin to be provided for other gradient axes to design waveforms of balancing gradients on the other gradient axes so as to generate a compensation field comparable to the concomitant field together with the balancing gradients of the other gradient axes as much as possible.

When the positive pulse Gz1 and the negative pulse Gz2 having the maximum amplitude (the first balancing pulse is fully loaded) is continuously present throughout T1, a maximum first compensatory Maxwell term Bm2 is provided to compensate for the concomitant field to the maximum extent on the corresponding first gradient axis Gz.However, as previously described, the amplitudes of the positive pulse Gz1 and the negative pulse Gz2 may not be the maximum amplitude. When the entire time period T1 is occupied and the maximum amplitude is transmitted such that the left-side Maxwell term is greater than the right-side Maxwell term, the amplitudes of the positive pulse Gz1 and the negative pulse Gz2 may be reduced in the same proportion to keep the difference between the Maxwell terms on both sides within ±a preset value.

As described above, the original gradient pulses include original gradient pulses disposed on the first gradient axis and original gradient pulses disposed on the second gradient axis, and in the embodiments of the present invention, the load of the original gradient pulses disposed on the first gradient axis is less than the load of the original gradient pulses disposed on the second gradient axis, so that when a fully-loaded first balancing pulse is disposed on the first gradient axis (e.g., the first balancing pulse has the maximum pulse amplitude and the first balancing pulse lasts throughout the time period T1), excessive balancing gradients on the second gradient axis can be avoided, thereby avoiding further increasing the burden on the second gradient axis. Therefore, the first gradient axis may be a gradient axis having a relatively small burden (an overall amplitude and/or duration of the gradient pulses on the first gradient axis is small), and the second gradient axis may be a gradient axis having a relatively large burden.

In some embodiments, the magnetic resonance imaging sequence further includes a phase encoding gradient axis (not shown in the figures) of a logical axis, and the phase encoding gradient axis corresponds to an axial direction of a physical axis of the magnetic resonance system. For example, the first gradient axis may be a layer selection gradient axis of the logical axis, and the second gradient axis may be a frequency encoding gradient axis of the logical axis. In the embodiments of the present invention, the phase encoding direction (or phase encoding gradient axis) of the logical axis corresponds to a z-axis direction of the physical axis of the magnetic resonance system, that is, an axial extension direction of a scanning chamber of the magnetic resonance system. In such a corresponding manner, a better image quality can be obtained.

Although the layer selection gradient axis Gz is used as the first gradient axis and the frequency encoding gradient axis Gx is used as the second gradient axis in FIG. 2, when the gradient load of the frequency encoding gradient axis Gx is smaller, the frequency encoding gradient axis Gx may also be used as the first gradient axis.

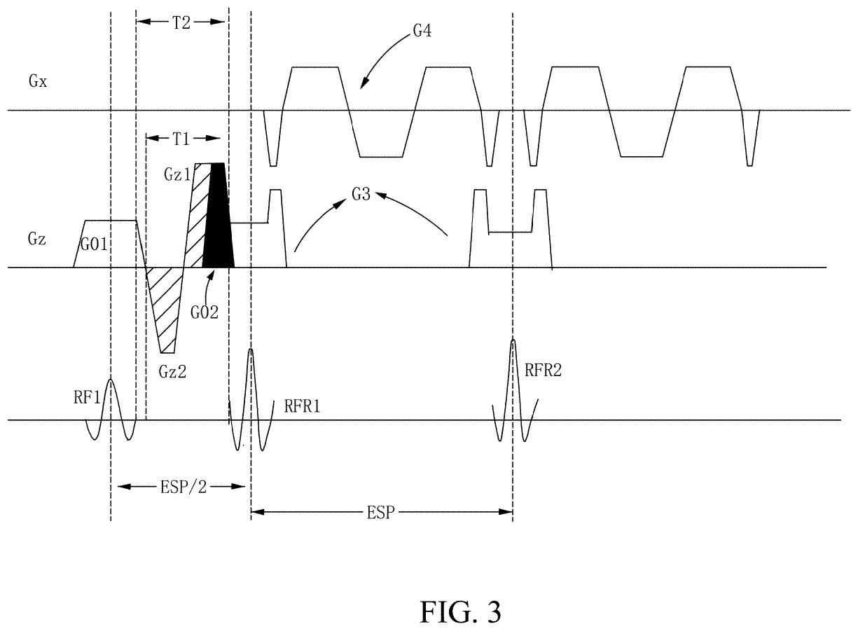

FIG. 3 shows a waveform diagram of a magnetic resonance imaging sequence according to another embodiment of the present application, which is similar to the waveform of FIG. 2, except that the right-side original pulse may include a gradient pulse G3 disposed on a first gradient axis and a gradient pulse G4 disposed on a second gradient axis. The gradient pulse on the second gradient axis satisfies flow compensation conditions. Those skilled in the art will appreciate that flow artifacts are eliminated or reduced by setting the gradient pulse that satisfies the flow compensation conditions.

In FIG. 3, a first balancing pulse (including a positive pulse Gz1 and a negative pulse Gz2) disposed on the first gradient axis is sufficient to compensate for a difference between a right-side Maxwell term Bm1 and a left-side Maxwell term Bm0. Thus, on the second gradient axis Gx, no gradient pulses need to be disposed between a radio-frequency excitation pulse RF1 and a first radio-frequency refocusing pulse RFR1 to perform additional compensation.

When the flow compensation conditions can be satisfied by disposing the right-side original pulse on the second gradient axis Gx, a left-side original pulse may not be disposed on the second gradient axis Gx.

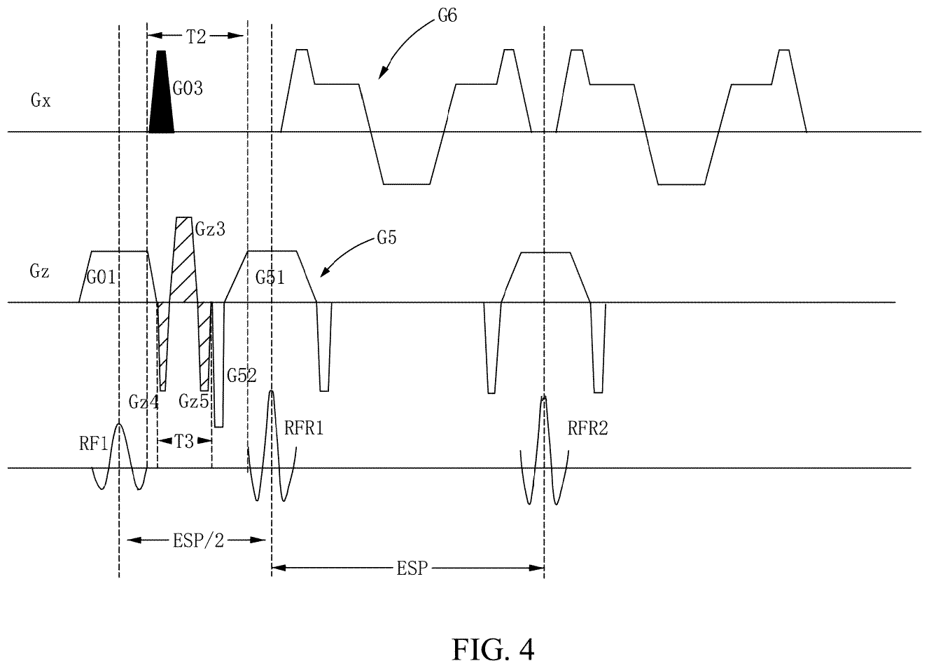

FIG. 4 shows a waveform diagram of a magnetic resonance imaging sequence according to yet another embodiment of the present application, which is similar to the waveform of FIG. 2, except that the gradient pulse may include a gradient pulse G5 disposed on a first gradient axis and a gradient pulse G6 disposed on a second gradient axis. The gradient pulse on the first gradient axis satisfies flow compensation conditions.

In FIG. 4, a first balancing pulse disposed on the first gradient axis satisfies the flow compensation conditions to avoid affecting an effect of flow compensation. For example, the first balancing pulse in FIG. 4 includes one positive pulse Gz3 and two negative pulses Gz4 and Gz5, where the negative pulses Gz4 and Gz5 have the same shape, and the waveform area of the positive pulse Gz3 is equal to the sum of waveform areas of the two negative pulses Gz4 and Gz5. Given that the flow compensation conditions are satisfied, concomitant fields are better compensated for by setting the positive pulse and the negative pulse at the same time. Similar to FIG. 2 and FIG. 3, the first balancing pulse is sufficient to compensate for a difference between a right-side Maxwell term Bm1 and a left-side Maxwell term Bm0. Therefore, on the second gradient axis Gx, there may be no balancing pulse between a radio-frequency excitation pulse RF1 and a first radio-frequency refocusing pulse RFR1 for additional compensation, or only an initial third gradient pulse G03.

Further, a left-side original pulse further includes fourth gradient pulses applied on the first gradient axis after the radio-frequency excitation pulse RF1, such as pulse G52 and pulse G51 (portions located on the left side of the first radio-frequency refocusing pulse RFR1) in FIG. 4, and the first balancing pulse (including one positive pulse Gz3 and two negative pulses Gz4 and Gz5) is located within a third time period T3, which is a time period within a first time period T1 in which the fourth gradient pulses are not applied. For example, the third time period T3 is a blank time period from the starting point of the first time period T1 to the starting point of the fourth gradient pulses.

A magnetic resonance imaging sequence provided by Embodiment 2 of the present invention is similar to that in Embodiment 1, where the magnetic resonance system further includes a second balancing pulse disposed on the second gradient axis, and the second balancing pulse is located within a second time period T2, which is located between the end point of the radio-frequency excitation pulse RF1 (that is, the end point of a plateau of the first gradient pulse G01) and the starting point of the first radio-frequency refocusing pulse RFR1. Those skilled in the art will appreciate that plateaus of the pulses of the magnetic resonance imaging sequence refer to time periods in which the amplitude of waveforms remains unchanged.

The second balancing pulse includes at least one of a positive pulse and a negative pulse.

In some embodiments, the third gradient pulse G03 forms at least a portion of the positive pulse or the negative pulse of the second balancing pulse (when the second balancing pulse is formed, the starting point of the third gradient pulse G03 may move within the second time period T2).

In some embodiments, the second balancing pulse may include one positive pulse and two negative pulses located on both sides of the one positive pulse, and the sum of the waveform areas of the two negative pulses is equal to the waveform area of the positive pulse.

The second balancing pulse is configured to further compensate for a difference between the right-side Maxwell term and the left-side Maxwell term, so that the absolute value of the difference between the Maxwell terms on both sides is finally less than or equal to a preset value, where the left-side Maxwell term is the sum of Maxwell terms generated by all gradient pulses in a time period from the center of the radio-frequency excitation pulse RF1 to the center of the first radio-frequency refocusing pulse RFR1, including a first compensatory Maxwell term generated by the first balancing pulse, a second compensatory Maxwell term generated by the second balancing pulse, and the sum of Maxwell terms generated by other left-side original gradient pulses. The right-side Maxwell term is half of a Maxwell term generated by a right-side original pulse.

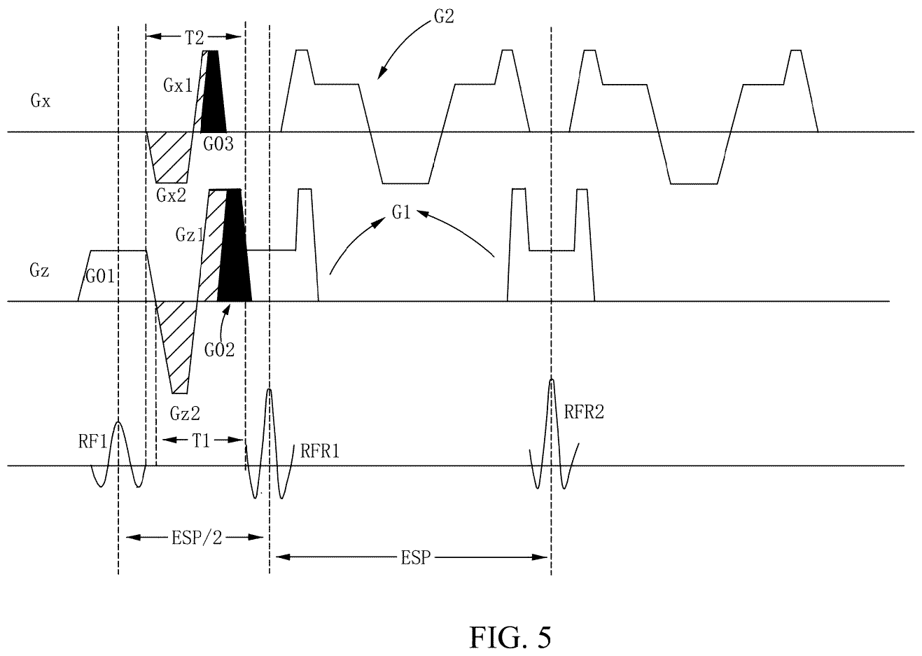

Embodiment 2 of the present invention will be described below with reference to FIGS. 5-7.

FIG. 5 shows a waveform diagram of a magnetic resonance imaging sequence according to another embodiment of the present application, where the magnetic resonance imaging sequence includes a radio-frequency excitation pulse RF1, a first radio-frequency refocusing pulse RFR1 and a second radio-frequency refocusing pulse RFR2 sequentially applied after the radio-frequency excitation pulse RF1, original gradient pulses, a first balancing pulse, and a second balancing pulse. The original gradient pulses include a left-side original pulse and a right-side original pulse.

The original gradient pulses may include a gradient pulse G1 disposed on a first gradient axis and a gradient pulse G2 disposed on a second gradient axis.

The first balancing pulse is configured to generate a first compensatory Maxwell term Bm2 as a compensation field to compensate for a difference (a first difference) between a right-side Maxwell term Bm1 and a current (or initial) left-side Maxwell term Bm0. The first balancing pulse includes a positive pulse Gz1 and a negative pulse Gz2 located on the first gradient axis.

The positive pulse Gz1 and the negative pulse Gz2 last throughout T1 and have a maximum amplitude allowable by a system, which allows a maximum first compensatory Maxwell term Bm2 to be provided, and allows more margin to be provided for other gradient axes to design waveforms of balancing gradients on the other gradient axes so as to generate a compensation field comparable to the concomitant field together with the balancing gradients of the other gradient axes as much as possible.

The waveform of the sequence shown in FIG. 5 is similar to that shown in FIG. 2, except that a second balancing pulse is further included, which may be disposed on the second gradient axis Gx and located within a second time period T2. As shown in FIG. 5, the second balancing pulse in the present embodiment includes a positive pulse Gx1 and a negative pulse Gx2 located on the second gradient axis Gx. However, in other implementations, the second balancing pulse may include only a positive pulse or a negative pulse. In some embodiments, the positive pulse Gx1 may include a third gradient pulse G03 as at least a portion of the left-side original pulse, that is, the third gradient pulse G03 may be used as a portion of the positive pulse Gx1. A new left-side Maxwell term Bm0′ is obtained by increasing the left-side Maxwell term Bm0 via the first balancing pulse, where:

$$B m {0}^{′} = B m 0 + B m 2$$

In some embodiments, when the second balancing pulse only includes the positive pulse Gx1, it may be necessary to increase the pulse amplitude or duration (which requires superimposing the increased duration onto the current ESP, causing the ESP to become larger) to obtain a sufficient compensation field, which increases the pulse burden on the second gradient axis and potentially leads to image blurring issues. However, it is also possible to generate a required compensation field, e.g., a second compensatory Maxwell term Bm3, by setting the negative pulse Gx2 such that there is no need to increase the ESP (or only increase the ESP by a small amount) and no need to increase the pulse amplitude (or only increase the pulse amplitude by a small amount). Ideally, a difference between the right-side Maxwell term Bm1 and the initial left-side Maxwell term Bm0 may be fully compensated for via the first compensatory Maxwell term Bm2 and the second compensatory Maxwell term Bm3, i.e.: (Bm1−Bm0) is equal to or approximately equal to (Bm2+Bm3). However, if under a current echo spacing, due to a limited time period allowed for adding balancing pulses, when the first compensatory Maxwell term Bm2 and the second compensatory Maxwell term Bm3 have both reached their maximums, the difference (Bm1−Bm0) still cannot be compensated for, then the echo spacing may be appropriately increased (correspondingly, the time periods T1 and T2 will also increase), and based on the increased echo spacing, the maximum value of the first compensatory Maxwell term Bm2 is redetermined (e.g., by setting a fully-loaded first balancing pulse). When an unbalanced field still exists, the second compensatory Maxwell term is determined based on the increased echo spacing (for example, by disposing the second balancing pulse) to compensate for the difference between the Maxwell fields on both sides of the first radio-frequency refocusing pulse. This process is iterated until a suitable balancing pulse (e.g., including only the first balancing pulse or further including the second balancing pulse) and a suitable echo spacing are determined.

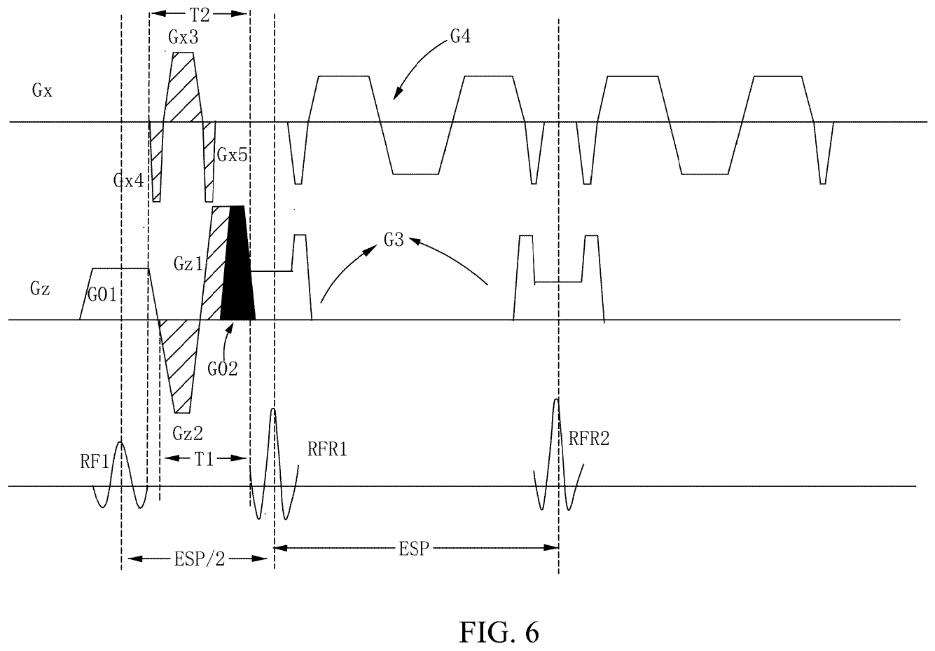

FIG. 6 shows a waveform diagram of a magnetic resonance imaging sequence according to another embodiment of the present application, where the magnetic resonance imaging sequence includes a radio-frequency excitation pulse RF1, a first radio-frequency refocusing pulse RFR1 and a second radio-frequency refocusing pulse RFR2 sequentially applied after the radio-frequency excitation pulse RF1, original gradient pulses, and a first balancing pulse.

The original gradient pulses may include a gradient pulse G3 disposed on a first gradient axis and a gradient pulse G4 disposed on a second gradient axis. The gradient pulse on the second gradient axis satisfies flow compensation conditions.

The first balancing pulse is configured to generate a first compensatory Maxwell term Bm2 as a compensation field to compensate for a difference between a right-side Maxwell term Bm1 and an initial left-side Maxwell term Bm0. The first balancing pulse includes a positive pulse Gz1 and a negative pulse Gz2 located on the first gradient axis Gz.

The positive pulse Gz1 and the negative pulse Gz2 last throughout T1 and have a maximum amplitude allowable by a system, which allows a maximum first compensatory Maxwell term Bm2 to be provided, and allows more margin to be provided for other gradient axes to design waveforms of balancing gradients on the other gradient axes so as to generate a compensation field comparable to the concomitant field together with the balancing gradients of the other gradient axes as much as possible.

The magnetic resonance imaging sequence of the present embodiment further includes a second balancing pulse, and the second balancing pulse is disposed on the second gradient axis Gx and is located within a second time period T2, for example, between the radio-frequency excitation pulse RF1 and the first radio-frequency refocusing pulse RFR1. The magnetic resonance imaging sequence of the present embodiment is similar to the sequence shown in FIG. 5, except that the second balancing pulse is a symmetrical pulse, and specifically, the symmetrical pulse includes a positive pulse Gx3 and two negative pulses Gx4 and Gx5 symmetrically disposed on both sides of the pulse Gx3, the positive pulse Gx3 and the negative pulses Gx4 and Gx5 have opposite directions, and the sum of the areas of the positive pulse Gx3 and the two negative pulses Gx4 and Gx5 is 0. The symmetrical pulse causes the second gradient axis Gx to satisfy flow compensation conditions while further compensating for the concomitant field.

Moreover, since the burden on the second gradient axis Gx is relatively larger than that on the first gradient axis Gz, after preliminary compensation is performed by disposing a fully-loaded first balancing pulse (including the positive pulse Gz1 and the negative pulse Gz2) on the first gradient axis Gz, further compensation is performed via the second balancing pulse (a symmetrical pulse), so that the second balancing pulse does not need to have an excessively large duration or amplitude, thereby avoiding image issues caused by an increased or excessively increased ESP, or overheating issues due to excessive gradient axis burdens, and further avoiding prolonging the repetition time (TR) of the sequence to reduce heating.

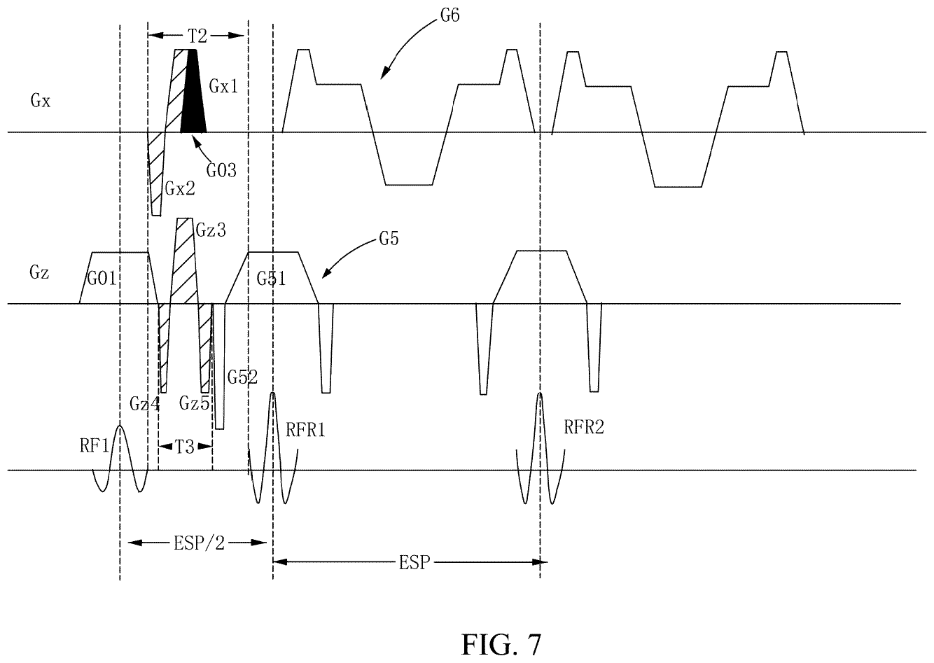

FIG. 7 shows a waveform diagram of a magnetic resonance imaging sequence according to another embodiment of the present application, where the magnetic resonance imaging sequence includes a radio-frequency excitation pulse RF1, a first radio-frequency refocusing pulse RFR1 and a second radio-frequency refocusing pulse RFR2 sequentially applied after the radio-frequency excitation pulse RF1, original gradient pulses, and a first balancing pulse.

The gradient pulses may include a gradient pulse G5 disposed on a first gradient axis Gz and a gradient pulse G6 disposed on a second gradient axis. The gradient pulse on the first gradient axis Gz satisfies flow compensation conditions.

The first balancing pulse is disposed on the first gradient axis Gz and located within a first time period T1. The first balancing pulse is configured to generate a maximum first compensatory Maxwell term Bm2 (maximum value of a first compensatory Maxwell term) as a compensation field to compensate for a difference (a first difference) between a right-side Maxwell term Bm1 and an initial left-side Maxwell term Bm0.

The first balancing pulse lasts throughout T1 of the first gradient axis and has a maximum amplitude allowable by a system, which allows a maximum first compensatory Maxwell term Bm2 to be provided, and allows more margin to be provided for other gradient axes to design waveforms of balancing gradients on the other gradient axes so as to generate a compensation field comparable to the concomitant field together with the balancing gradients of the other gradient axes as much as possible.

The magnetic resonance imaging sequence of the present embodiment may further include a second balancing pulse, the second balancing pulse is disposed on the second gradient axis Gx and located within a second time period T2 between the radio-frequency excitation pulse RF1 and the first radio-frequency refocusing pulse RFR1, and the second balancing pulse may include, for example, at least one of a positive pulse Gx1 and a negative pulse Gx2. The magnetic resonance imaging sequence of the present embodiment is similar to the sequences shown in FIG. 4 and FIG. 6, except that the first balancing pulse is a symmetrical pulse, and specifically, the first balancing pulse includes a third pulse Gz3 and two fourth pulses Gz4 and Gz5 symmetrically disposed on both sides of the third pulse Gz3, the third pulse Gz3 and the fourth pulse Gz4 and Gz5 have opposite directions, the two fourth pulses are identical in shape, and the sum of the areas of the third pulse Gz3 and the fourth pulse Gz4 and Gz5 is 0, thereby satisfying flow compensation conditions.

Moreover, the sequence shown in FIG. 7 further includes a second balancing gradient, e.g., including the positive pulse Gx1 and the negative pulse Gx2 described above, disposed on the second gradient axis Gx. Since the echo spacing is limited, the first balancing pulse may not be able to generate a sufficient left-side Maxwell field due to a limited duration (even if the maximum value of the first compensatory Maxwell field Bm2 is reached). Therefore, after preliminary compensation is performed by disposing the first balancing pulse (a symmetrical pulse) on the first gradient axis Gz, a second compensatory Maxwell field Bm3 is obtained by means of the second balancing pulse, thereby avoiding image issues caused by excessively increasing the ESP, or overheating due to excessive gradient axis burdens, and further preventing prolonging the repetition time (TR) of the sequence to reduce heating.

The first balancing pulse in the magnetic resonance imaging sequence in any one of the above embodiments may be determined based on an echo spacing. For example, based on a current echo spacing, a maximum compensatory Maxwell term, i.e., the maximum value of the first compensatory Maxwell term, that can be generated by the first gradient axis may be calculated. Since what needs to be compensated for is a difference between left-side and right-side concomitant fields, a corresponding first balancing pulse may be set by obtaining a difference between the maximum value of the first compensatory Maxwell term and the difference to be compensated for between the concomitant fields. For example, the first balancing pulse is fully loaded within the time period T1, and when the difference is small, the positive pulse and the negative pulses of the first balancing pulse are set to have small amplitudes, otherwise, the positive pulse and the negative pulses of the first balancing pulse may be allowed to have maximum amplitudes. Alternatively, when the first gradient axis already has a left-side original pulse (a second gradient pulse G02), and when the difference is small, a negative pulse (or a symmetrical pulse having a small amplitude) is additionally set, and when the difference is large, the second gradient pulse G02 is adjusted to the maximum amplitude and the width thereof is appropriately increased, and a negative pulse having the maximum amplitude (or a symmetrical pulse having the maximum amplitude) is set.

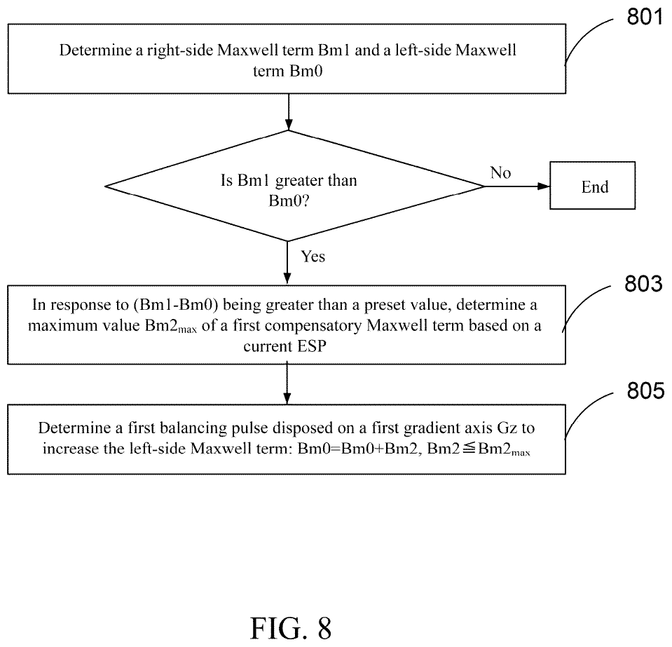

Embodiment 3 of the present application will be described below with reference to FIGS. 8 to 10.

Embodiment 3 of the present application provides an optimization method for a magnetic resonance imaging sequence, based on which the magnetic resonance imaging sequence according to any one of the above embodiments can be obtained. The magnetic resonance imaging sequence includes a radio-frequency excitation pulse RF1, a first radio-frequency refocusing pulse RFR1 and a second radio-frequency refocusing pulse RFR2 sequentially applied after the radio-frequency excitation pulse RF1, and original gradient pulses. The radio-frequency excitation pulse RF1, the first radio-frequency refocusing pulse RFR1, the second radio-frequency refocusing pulse RFR2, and the original gradient pulses may be similar to the corresponding pulses in FIGS. 2 to 7.

FIG. 8 shows a flowchart of an embodiment of the optimization method, including a first step 801, a second step 803, and a third step 804. In the first step 801, a right-side Maxwell term Bm1 generated by a right-side original pulse and a left-side Maxwell term Bm0 generated by a left-side original pulse are determined. The right-side or left-side Maxwell term can be determined by a simplified version of Equation (7), for example, by the following Equation (8).

$${B}_{m} = \frac{1}{2 {B}_{0}} ( {G}_{x}^{2} + {G}_{z}^{2} ) {y}^{2} \qquad ( 8 )$$

In some embodiments, it is determined that the right-side Maxwell term Bm1 may be a minimum Maxwell term obtained after appropriate adjustment of the original pulses between the center of the first radio-frequency refocusing pulse RFR1 and the center of the second radio-frequency refocusing pulse RFR2, the adjustment for example including: reducing the amplitudes of the gradient pulses as much as possible while satisfying clinical imaging requirements. The initially determined left-side Maxwell term Bm0 (generated by the left-side original pulse) may be an initial left-side Maxwell term, which is generated by any initial left-side gradient pulses (e.g., including part of a first gradient pulse G01, a second gradient pulse G02, a third gradient pulse G03, part of a fourth gradient pulse, etc.) between the center of the radio-frequency excitation pulse RF1 and the center of the first radio-frequency refocusing pulse RFR1.

In the second step 803, in response to the right-side Maxwell term Bm1 being greater than the left-side Maxwell term (Bm0) and a first difference (Bm1−Bm0) between the right-side Maxwell term Bm1 and the left-side Maxwell term (Bm0) being greater than a preset value (e.g., 0 or a positive number close to 0), a maximum value (Bm2ₘₐₓ) of a first compensatory Maxwell term Bm2 that can be generated on a first gradient axis Gz is determined based on a current echo spacing (ESP) of the magnetic resonance imaging sequence. Specifically, when the echo spacing is determined, a first time period T1 is determined. Assuming that a left-side gradient pulse fully covering the first time period T1 and having a maximum amplitude (maximum transmission amplitude allowed by the system) is disposed on the first gradient axis Gz, the maximum amplitude of the left-side gradient pulse is substituted into Formula (8) to obtain a maximum value of the left-side first Maxwell term Bm2 (hereinafter referred to as maximum value Bm2ₘₐₓ).

When the difference between the right-side Maxwell term Bm1 and the left-side Maxwell term Bm0 is less than or equal to the preset value, the optimization method can be terminated, for example, without setting additional balancing gradients, the initial left-side gradient pulse can be maintained or adjusted to balance then duration and amplitude (e.g., in the case of the current ESP allowance, the Maxwell term is reduced by means of amplitude reduction and duration increase).

In the third step 805, a first balancing pulse disposed on the first gradient axis Gz is determined to increase the left-side Maxwell term Bm0. For example, the first balancing pulse generates a first compensatory Maxwell term Bm2 to increase the left-side Maxwell term: Bm0′=Bm0+Bm2, where the first balancing pulse is located within the first time period T1 or within a third time period T3 in the first time period T1, and the first balancing pulse includes a positive pulse and a negative pulse, where in response to the maximum value Bm2ₘₐₓ being greater than the first difference (Bm1−Bm0), the amplitude of the first balancing pulse is less than the maximum amplitude. In response to the first difference (Bm1−Bm0) between the maximum values being equal to the first difference (Bm1−Bm0), the amplitude of the first balancing pulse is equal to the maximum amplitude. Specifically, when flow compensation conditions do not need to be satisfied, the first balancing pulse may include a positive pulse and a negative pulse (Gz1 and Gz2); and when the first gradient axis Gz needs to satisfy the flow compensation conditions, the first balancing pulse may include a symmetrical pulse, for example, includes the third pulse Gz3 and the two fourth pulses Gz4, Gz5.

Further, in response to the maximum value Bm2ₘₐₓ being less than first difference (Bm1−Bm0), the amplitude of the first balancing pulse is equal to the maximum amplitude. By setting the first balancing pulse having the maximum amplitude, a maximum first compensatory Maxwell term, i.e., the maximum value Bm2ₘₐₓ, is obtained, which can maximally compensate for the difference between the Maxwell terms on both sides, thereby reducing artifacts caused by concomitant fields.

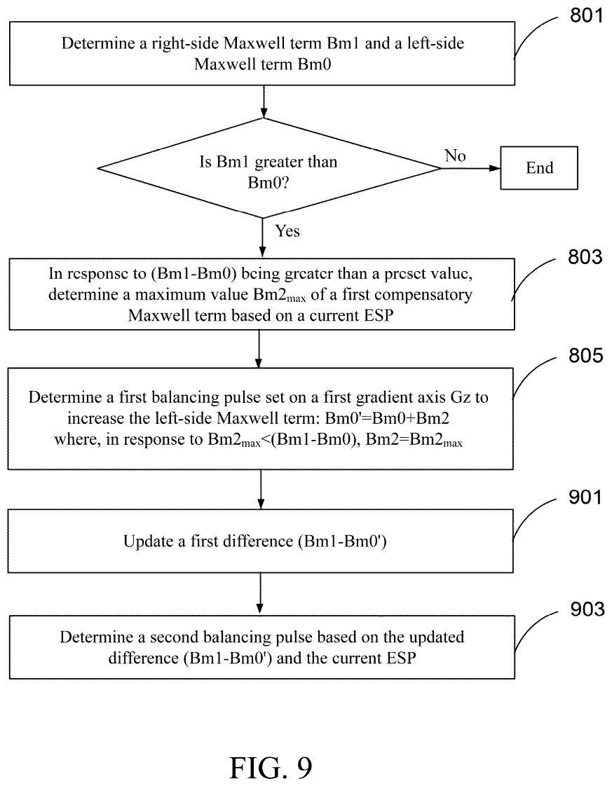

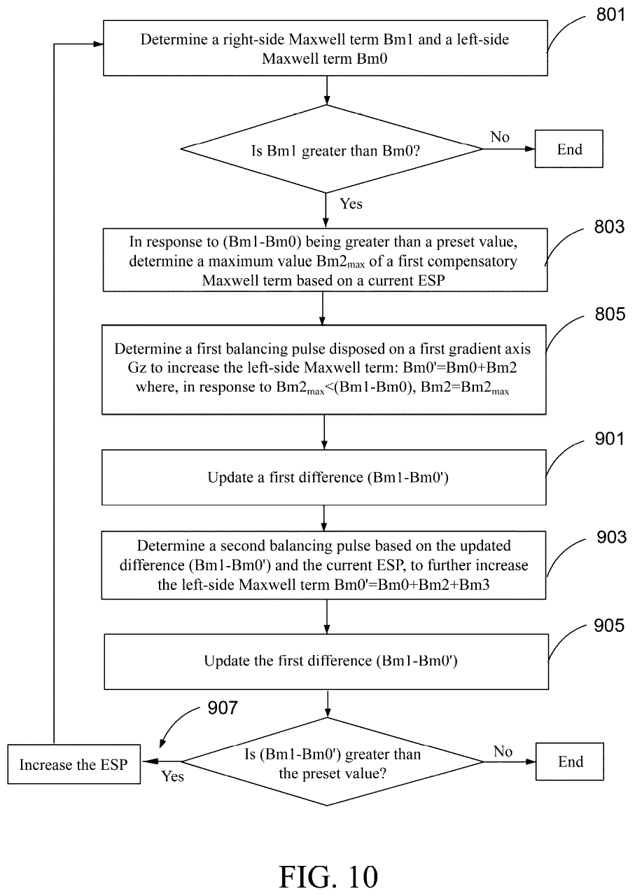

Since the maximum value Bm2ₘₐₓ is less than the first difference (Bm1−Bm0), the difference cannot be completely compensated for even if the first balancing pulse having the maximum amplitude is disposed. Therefore, further compensation can be performed by disposing a second balancing pulse, which will be described below with reference to FIG. 9 and FIG. 10.

In some embodiments, the original gradient pulses may include original gradient pulses disposed on the first gradient axis Gz and original gradient pulses located on the second gradient axis. The second gradient axis Gx has a heavier pulse burden than the first gradient axis Gz, and the majority of the right-side Maxwell term Bm1 is contributed to by the original gradient pulses on the second gradient axis.

Therefore, the first balancing pulse resulting in a maximum first compensatory Maxwell term Bm2 is disposed on the first gradient axis Gz, which prevents the second gradient axis from being further burdened, and further avoids the need to prolong the repetition time (TR) (e.g., by adding pulse-inclusive wait times to the original TR) to mitigate overheating risks when excessive heat is generated on the second gradient axis.

FIG. 9 shows a flow chart of another embodiment of the optimization method, which includes a first step 801, a second step 803, and a third step 805. The method shown in FIG. 9 is similar to the method shown in FIG. 8, except that when the maximum value Bm2ₘₐₓ is less than the first difference (Bm1−Bm0), the first balancing pulse has a maximum amplitude and thus produces the maximum value Bm2ₘₐₓ of the first compensatory Maxwell term. The method further includes a fourth step 901 and a fifth step 903. In the fourth step 901, the first difference is updated based on an increased left-side Maxwell term, e.g., a maximum value Bm2ₘₐₓ of a newly generated first compensatory Maxwell term and an initial left-side Maxwell term Bm0 may be added to obtain an updated left-side Maxwell term Bm0′, i.e.:

$$B m {0}^{′} = B m {2}_{max} + B m 0$$

the first difference is updated as (Bm1−Bm0′).

It should be noted that when the first balancing gradient includes an original pulse (e.g., a second gradient pulse G02), a newly generated left-side Maxwell term Bm2 or the maximum value Bm2ₘₐₓ only includes a left-side Maxwell term generated by the newly increased first balancing gradient and does not include a left-side Maxwell term generated by the original pulse. For example, if the positive pulse Gz1 (having the maximum amplitude) is entirely the originally existing second gradient pulse G02, it generates an initial left-side Maxwell term Bmz1, and during optimization, it is entirely used as the positive pulse Gz1 of the first balancing gradient and a new negative pulse Gz2 is added, then it generates a new left-side Maxwell term Bmz2, then:

$$B m {2}_{max} = B m z 2$$

For another example, if the positive pulse Gz1 includes a second gradient pulse G02, it generates an initial left-side Maxwell term Bmz0, the positive pulse (e.g., expressed as Gz1_{new}) of another part (Gz1−G02) generates a new left-side Maxwell term Bmz1_{new}, optimization is performed, a new negative pulse Gz2 is added, and a new left-side Maxwell term Bmz2 is generated, then:

$$B m {2}_{max} = B m z {1}_{n e w} + B m z 2$$

The above examples also applicable to the case where the second balancing gradient also includes original pulses, which will not be repeated here.

In the fifth step 903, a second balancing pulse is determined based on the updated first difference (Bm1−Bm0′) and a current echo spacing to further increase the left-side Maxwell term. For example, the second balancing pulse generates a second compensatory Maxwell term Bm3. Specifically, the second balancing pulse is disposed on the second gradient axis Gx and located within a second time period T2. As described in the above embodiments, the second balancing pulse may include at least one of a positive pulse and a negative pulse, and when flow compensation conditions need to be satisfied on the second gradient axis Gx, the second balancing pulse may also include a symmetrical pulse.

The second balancing pulse may not be fully loaded, for example, less than the maximum amplitude allowed by the system, and only lasts for a part of the second time period T2, instead of occupying the entire second time period T2. However, when the second compensatory Maxwell term Bm3 cannot fully compensate for the updated first difference (Bm1−Bm0′), it may be necessary to increase the amplitude or width (duration) of the second balancing gradient.

If the maximum second compensatory Maxwell term Bm3 generated by setting a fully loaded second balancing pulse still cannot fully compensate for the updated first difference (Bm1−Bm0′), a current ESP needs to be adjusted to obtain a larger compensation space, which can be described below with reference to FIG. 10.

FIG. 10 shows a flow chart of another embodiment of the optimization method, including a first step 801, a second step 803, a third step 805, a fourth step 901, and a fifth step 903. The method shown in FIG. 10 is similar to the method shown in FIG. 9, except that the method shown in FIG. 10 further includes a sixth step 905 and a seventh step 907. In the sixth step 905, the first difference is updated based on the left-side Maxwell term increased in the fifth step. Specifically, the left-side Maxwell term that has been updated via the first balancing pulse is further updated based on the left-side second Maxwell term Bm3, for example, as expressed by the following equation:

$$B m {0}^{′} = B m 0 + B m {2}_{max} + B m 3$$

The first difference is: (Bm1−Bm0′).

In the seventh step 907: in response to the first difference between the right-side Maxwell term and the left-side Maxwell term Bm0′ updated via the second balancing pulse being still greater than the preset value, the echo spacing (ESP) is increased and the process returns to the first step 801 until the first difference is not greater than the preset value. The optimization method for a magnetic resonance imaging sequence in the present embodiment can be iteratively repeated until the difference between the Maxwell fields on both sides is fully compensated for, and on this basis, a small echo spacing (or a small increase in the current echo spacing) is determined to avoid image issues caused by excessively large echo spacings.

The embodiments of the present application may further provide a magnetic resonance system including a scanner and a processor, where the processor executes the optimization method for a magnetic resonance imaging sequence according to any one of the above embodiments or controls the scanner to execute the magnetic resonance imaging sequence according to any one of the above embodiments. The magnetic resonance system in the present embodiment may include the magnetic resonance system shown in FIG. 1, and the processor therein may be disposed, for example, in the computer system 120 or the system controller 130.

In addition to any previously indicated modifications, many other variations and replacement arrangements may be devised by those skilled in the art without departing from the substance and scope of the present description, and the appended claims are intended to encompass such modifications and arrangements. Therefore, although the information has been described above in specifics and detailed terms in connection with what is currently considered to be the most practical and preferred aspects, it will be apparent to those of ordinary skill in the art that many modifications can be made, including but not limited to the form, function, mode of operation, and use, without departing from the principles and concepts set forth herein. Likewise, as used herein, in all respects, the examples and embodiments are intended to be illustrative only and should not be construed as limiting in any way.

The purpose of providing the above specific embodiments is to facilitate understanding of the content disclosed in the present invention more thoroughly and comprehensively, but the present invention is not limited to these specific embodiments. Those skilled in the art should understand that various modifications, equivalent replacements, and changes can also be made to the present invention and should be included in the scope of protection of the present invention as long as these changes do not depart from the spirit of the present invention.

1. A magnetic resonance imaging sequence, comprising:
a radio-frequency excitation pulse;
a first radio-frequency refocusing pulse and a second radio-frequency refocusing pulse sequentially applied after the radio-frequency excitation pulse;
original gradient pulses comprising a right-side original pulse and a left-side original pulse, the right-side original pulse being applied between the center of the first radio-frequency refocusing pulse and the center of the second radio-frequency refocusing pulse, the left-side original pulse being applied between the center of the radio-frequency excitation pulse and the center of the first radio-frequency refocusing pulse, and the left-side original pulse comprising a first gradient pulse corresponding to the radio-frequency excitation pulse; and
a first balancing pulse located within a first time period between the end point of the first gradient pulse and the starting point of the first radio-frequency refocusing pulse and comprising a positive pulse and a negative pulse located on a first gradient axis.

2. The magnetic resonance imaging sequence according to claim 1, wherein the left-side original pulse comprises a second gradient pulse applied on the first gradient axis after the radio-frequency excitation pulse, wherein the second gradient pulse forms at least a portion of the positive pulse or the negative pulse of the first balancing pulse.

3. The magnetic resonance imaging sequence according to claim 2, wherein the first balancing pulse lasts throughout the first time period.

4. The magnetic resonance imaging sequence according to claim 1, wherein at least one of the positive pulse and the negative pulse of the first balancing pulse has a maximum pulse amplitude allowed to be transmitted by a magnetic resonance system.

5. The magnetic resonance imaging sequence according to claim 1, wherein the pulse amplitudes of the positive pulse and the negative pulse of the first balancing pulse are both less than a maximum pulse amplitude allowed to be transmitted by a magnetic resonance system.

6. The magnetic resonance imaging sequence according to claim 1, wherein the original gradient pulses comprise original gradient pulses disposed on the first gradient axis and original gradient pulses disposed on a second gradient axis, and the load of the original gradient pulses on the second gradient axis is greater than the load of the original gradient pulses on the first gradient axis.

7. The magnetic resonance imaging sequence according to claim 6, wherein the magnetic resonance imaging sequence further comprises a second balancing pulse disposed on the second gradient axis, the second balancing pulse is located within a second time period, and the second time period is located between the end point of the radio-frequency excitation pulse and the starting point of the first radio-frequency refocusing pulse.

8. The magnetic resonance imaging sequence according to claim 7, wherein the second balancing pulse comprises at least one of a positive pulse and a negative pulse.

9. The magnetic resonance imaging sequence according to claim 8, wherein the left-side original pulse comprises:
a third gradient pulse applied on the second gradient axis within the second time period, wherein the third gradient pulse forms at least a portion of the positive pulse or the negative pulse of the second balancing pulse.

10. The magnetic resonance imaging sequence according to claim 1, wherein the first balancing pulse comprises one positive pulse and two negative pulses located on both sides of the one positive pulse, and the sum of the waveform areas of the two negative pulses is equal to the waveform area of the one positive pulse.

11. The magnetic resonance imaging sequence according to claim 10, wherein the left-side original pulse comprises a fourth gradient pulse applied on the first gradient axis after the radio-frequency excitation pulse, wherein the first balancing pulse is located within a third time period that is a time period within the first time period in which the fourth gradient pulse is not applied.

12. The magnetic resonance imaging sequence according to claim 7, wherein the second balancing pulse comprises one positive pulse and two negative pulses located on both sides of the one positive pulse, and the sum of the waveform areas of the two negative pulses is equal to the waveform area of the one positive pulse.

13. The magnetic resonance imaging sequence according to claim 6, wherein the first gradient axis is a layer-selection gradient axis on a logical axis, and the second gradient axis is a frequency encoding gradient axis on the logical axis.

14. The magnetic resonance imaging sequence according to claim 13, further comprising a phase encoding gradient axis on the logical axis, the phase encoding gradient axis on the logical axis corresponding to an axial direction of a physical axis of a magnetic resonance system.

15. The magnetic resonance imaging sequence according to claim 1, comprising a fast spin echo sequence.

16. An optimization method for a magnetic resonance imaging sequence, the magnetic resonance imaging sequence comprising:
a radio-frequency excitation pulse, a first radio-frequency refocusing pulse and a second radio-frequency refocusing pulse sequentially applied after the radio-frequency excitation pulse, and original gradient pulses, the original gradient pulses comprising a right-side original pulse and a left-side original pulse, the right-side original pulse being applied between the center of the first radio-frequency refocusing pulse and the center of the second radio-frequency refocusing pulse, the left-side original pulse being applied between the center of the radio-frequency excitation pulse and the center of the first radio-frequency refocusing pulse, and the left-side original pulse comprising a first gradient pulse corresponding to the radio-frequency excitation pulse; and the method comprising:
step 1: determining a right-side Maxwell term generated by the right-side original pulse and a left-side Maxwell term generated by the left-side original pulse;
step 2: in response to the right-side Maxwell term being greater than the left-side Maxwell term and a first difference between the right-side Maxwell term and the left-side Maxwell term being greater than a preset value, based on a current echo spacing of the magnetic resonance imaging sequence, determining a maximum value of a first compensatory Maxwell term capable of being generated on a first gradient axis; and
step 3: determining a first balancing pulse disposed on the first gradient axis to increase the left-side Maxwell term, and in response to the maximum value being greater than the first difference, the amplitude of the first balancing pulse being less than a maximum amplitude; and in response to the maximum value being equal to the first difference, the amplitude of the first balancing pulse being equal to the maximum amplitude; wherein the first balancing pulse is located within a first time period between the end point of the first gradient pulse and the starting point of the first radio-frequency refocusing pulse, and the first balancing pulse comprises a positive pulse and a negative pulse.

17. The method according to claim 16, wherein in response to the maximum value being less than the first difference, the amplitude of the first balancing pulse is equal to the maximum amplitude, and the method further comprises:
step 4: updating the first difference based on the increased left-side Maxwell term; and
step 5: determining a second balancing pulse based on the updated first difference and the current echo spacing to further increase the left-side Maxwell term, wherein the second balancing pulse is disposed on a second gradient axis and located between the end point of the radio-frequency excitation pulse and the starting point of the first radio-frequency refocusing pulse.

18. The method according to claim 17, further comprising:
step 6: updating the first difference based on the left-side Maxwell term increased in step 5; and
step 7: in response to the right-side Maxwell term being greater than the left-side Maxwell term and the first difference being greater than the preset value, increasing the echo spacing and returning to step 1.

19. The method according to claim 16, wherein the original gradient pulses comprise original gradient pulses disposed on the first gradient axis and original gradient pulses located on a second gradient axis, and the load of the original gradient pulses on the second gradient axis is greater than the load of the original gradient pulses on the first gradient axis.

20. A magnetic resonance system, comprising:
a scanner; and
a processor configured to control the scanner to execute the magnetic resonance imaging sequence according to claim 1.
